(19) United States
(12) Patent Application Publication
(10) Pub. No.: US 2011/0199097 A1
(43) Pub. Date: Aug. 18, 2011

(54) Sensor system with reduced sensitivity to sample placement

(76) Inventor: Larry Dowd Hartsough, Berkeley, CA (US)

(21) Appl. No.: 12/998,401

(22) PCT Filed: Oct. 14, 2009
(86) PCT No.: PCT/US2009/005611

§ 371 Date: Apr. 15, 2011

Related U.S. Application Data
(60) Provisional application No. 61/196,954, filed on Oct. 22, 2008.

(51) Int. Cl. G01R 27/04

(52) U.S. Cl. 324/629

(57) ABSTRACT

The present invention relates to the non-invasive analysis of materials in both in-vivo and ex-vivo configurations that show reduced sensitivity to sample placement within the sample measurement location. Embodiments of the apparatus make use of paired magnetic configurations and/or paired electrode configurations. Methods are described that compensate for the variation in sample size, and volume to give accurate and repeatable results.

### FIELD OF INVENTION

The present invention relates generally to the field of non-invasive, non-destructive analysis and identification of organic and inorganic substances. Analysis may comprise identification of materials in solid or liquid form or the measurement of the concentration of molecules in a mixture or solution. Applications arise in a number of fields, such as medicine, biology, biometrics, industrial process monitoring, and the identification of substances such as hazardous materials and illegal drugs, among others. In particular, some embodiments of the invention relate to the in-vivo measurement of glucose in the blood of a human subject.

### BACKGROUND OF THE INVENTION

Diabetes, the inability of the body to maintain blood glucose at normal levels, is a large and increasing health problem. To enable effective treatment, by injection of insulin or control of diet, persons with diabetes require frequent self-monitoring of blood glucose levels. For the most effective blood glucose control, monitoring should take place every few hours.

The usual method currently used for blood glucose monitoring is by analysis of a drop of blood extracted from a finger prick. As this is painful and unpleasant, diabetics often do not perform monitoring as often as recommended. This increases the risk of serious consequences, such as insulin shock or diabetic coma.

Therefore, a number of non-invasive methods for blood glucose monitoring have been proposed. Optical techniques using transmission and/or absorption of infrared electromagnetic radiation appear to have many shortcomings due to extensive calibration requirements, low signal strength and strong interference with the signal. Nuclear magnetic resonance (NMR), has also been used to detect glucose in blood. However, NMR requires strong and complex fixed as well as varying magnetic fields, in addition to very complex analytical equipment. Hence, NMR is a rather expensive technique.

Another technique exploits the interaction of molecules with radio frequency (RF) electric fields. Placement of a sample within the path of an RF signal from one electrode (antenna or transmitter) to another (receiver) alters the signal strength or resonance at certain frequencies specific to the sample. Analogous to optical spectroscopy, the path length of the signal and the amount of sample within that path affects the signal at the receiver.

U.S. Pat. No. 7,315,767 by Caduff et al, describes an apparatus in which a pair of coplanar electrodes is placed in contact or close proximity to a target object that contains the substance to be measured (e.g., a human limb in the case of blood glucose measurement). These electrodes are part of a circuit that includes apparatus for measuring circuit behavior such as signal strength, phase relationships, and resonant frequency. Voltage at modulated radio frequencies (RF) is applied between the electrodes and changes in the operating characteristics of the circuit due to the presence of the target are measured. There are a number of problems with using this device to measure blood glucose. For example, the signal strength is low, hence affected by interference and sample proximity to the electrodes, and is also affected by skin moisture and temperature. These can be affected by the way the device is used, i.e., strapping it to an arm can cause the skin temperature to rise and sweat to build up. Too much pressure may reduce the amount of blood in tissue adjacent to the electrodes. The shape of the electrodes can affect the consistency of the readings. In the case of this device, the preferred embodiments have an elongate central electrode surrounded by a ‘racetrack’ outer electrode. It is designed to be used with the long axis of the electrode parallel to the longitudinal axis of the limb and in close proximity to the skin. In the embodiments shown in the Caduff '767 patent, the distance from central to outer electrode is not constant. Hence, the electric field strength will vary with location, especially at the ends of the electrode array. It can be appreciated that slight rotational changes with respect to the axis of the arm may affect the readings. A similar device, having some of the same limitations, using non-coplanar electrodes designed to accommodate a human finger was described by Fuller in U.S. Pat. No. 5,792,668.

Another device using the interaction of substances with RF electric fields is described in U.S. Pat. No. 6,723,048 by Fuller and U.S. Pat. No. 7,316,649 by Fuller. In this apparatus, permanent magnets are arranged to create a magnetic field in which the transmitting (t) and receiving (r) electrodes are disposed. The electrodes are shaped to conform to a cavity in the device into which a person's finger is placed in contact with or close proximity to the electrodes. It is taught that the presence of the magnetic field increases RF signal-to-noise ratio and that the signal is affected by orientation of the magnetic field. Voltage imposed across the electrodes is swept over a frequency range (MHz to GHz) and the resulting spectrum of signal strength vs frequency is analyzed to extract the desired information about the sample.

A known drawback to devices using the alteration of an RF signal by the sample is the sensitivity of the resultant signal to the placement of the sample in relationship to the electrodes, as has been discussed by Fuller et al, U.S. Pat. No. 5,792,668, for example. That is, variation of sample placement or size will change the strengths of the electric and magnetic fields intersecting the sample and the volume of the sample intersected by the signals that reach the receiving electrode. Of necessity for practical application in the measurement of fingers, the diameter and length of the sample cavity and the spacing of the peripheral electrodes must be able to accommodate fingers that are at the upper range of human size. Because a person may not place his finger in the cavity in the exact same position from time-to-time, the readings made at different times will depend not only on changes in the characteristic being measured (i.e., blood glucose), but on variability of finger placement.

The technology may also be applied to the analysis of unknown materials in an ex-vivo application. In this case, the technology may be used to identify an unknown substance wherein the substance may be a liquid or powder. The scan of the sample is compared to scans for substances contained in a database. A small, portable device encompassing this technology may be useful in law enforcement, customs enforcement, hazardous materials response, and transportation security, among others. There are several difficulties with this method. First, as the amount of material loaded into the sample holder is varied, the signal strength changes. For instance, less material may be available than is required to fill the sample holder to the ‘standard’ level. To compensate for this, the database would need to contain stored spectra for different amounts of any given material. This increases the size of the required database. Second, as the database size increases, due to the tens, or hundreds, of thousands of possible materials and the redundancy due to material amount, three things may happen: a) search times may become very long; b) the chance may increase that multiple materials will ‘match’, resulting in ambiguous identification; and c) the database size may become too large to be stored in the memory local to a portable device.

Therefore, a need exists in the art for a sensing device based on the interaction of substances with RF electric fields that has increased signal strength and reduced sensitivity to variations in sample size and placement during measurement. A need also exists for methods to improve the speed and reliability of substance identification.

### SUMMARY OF THE INVENTION

Accordingly and advantageously, the present invention provides an apparatus that increases the volume of a given sample that interacts with the imposed electromagnetic fields and reduces variation in the received signal due to changes in sample placement. Various embodiments that provide these improvements comprise one or more of the following features:

1) magnets arranged in a multipolar array adjacent to the sample cavity so as to create multiple magnetic fields therein (achieved by having adjacent poles of opposite polarity);

2) electrodes arranged in a multipolar array adjacent to the sample cavity, but located closer to the sample than the poles of the magnets, so as to create multiple transmitter-receiver (t-r) pairs (achieved by having adjacent electrodes of complementary function; that is, t will always be adjacent to r and vice versa);

3) having at least one t-r pair of electrodes flexibly arranged with respect to the sample cavity to conform to samples of varying size and shape;

4) having at least one t-r pair of electrodes and their associated magnets flexibly arranged to conform to samples of varying size and shape;

5) having the ability to vary the relative positions of the electrodes with respect to the magnetic fields so as to optimize the signal for a given application;

6) providing an apparatus to switch the transmitting and receiving functions of the electrodes during an analysis session and combining the spectra so as to reduce the dependence of the combined spectrum on sample position, instrument variability, interferences and noise.

In addition, some embodiments of the present invention present a method of operation, when such a device is used for analysis and identification of substances, to increase the speed of analysis and improve the reliability of the analysis.

These and other advantages are achieved in accordance with the present invention as described in detail below.

### BRIEF DESCRIPTION OF THE DRAWINGS

To facilitate understanding, identical reference numerals have been used, where possible, to designate identical elements that are common to the figures. The drawings are not to scale and the relative dimensions of various elements in the drawings are depicted schematically and not necessarily to scale.

The techniques of the present invention can readily be understood by considering the following detailed description in conjunction with the accompanying drawings, in which:

FIG. 1 Shows a device of the U.S. Pat. No. 7,315,767 by Caduff et al. This is the device illustrated in FIG. 4 of that patent. The reference numbers in FIG. 1 are from the '767 patent and do not apply herein.

FIG. 2 is a top view of an apparatus according to the U.S. Pat. No. 6,723,048 by Fuller. This is the device illustrated in FIG. 3 of that patent. The reference numbers in FIG. 2 are from the '048 patent and have been adopted herein.

FIG. 3a is a representation of a vertical section through A-A of FIG. 2, showing the relationship of the magnets, the electrodes and the sample location. The reference numbers in FIG. 3a are from the '048 patent by Fuller and have been adopted herein.

FIG. 3b is a schematic of FIG. 3a wherein the magnetic lines of force have been added.

FIG. 4 is a representation of a cross-section through one embodiment of the present invention and the results of a model of the magnetic lines of force.

FIG. 5 is a representation of a cross-section through another embodiment of the present invention and the results of a model of the magnetic lines of force.

FIG. 6 is a representation of a cross-section through another embodiment of the present invention and the results of a model of the magnetic lines of force.

This embodiment illustrates an apparatus with a reduced size.

FIG. 7 illustrates an embodiment including a moveable electrode to accommodate samples of differing size.

FIGS. 8a-d illustrate alternate moveable electrode embodiments.

FIGS. 9a-c illustrate embodiments in which both the magnets and electrodes move.

FIGS. 10a-b depict magnetic model results for a simplified device based on the embodiments of FIG. 9.

FIGS. 11a-b are schematic depictions of embodiments in which electrode functionality can be switched.

FIGS. 12a-b are schematic cross-sections of typical embodiments with coplanar arrays of electrodes with penetrating magnetic flux lines.

FIGS. 13a-b are schematic cross-sections of typical embodiments with coplanar arrays of electrodes with enclosing magnetic flux lines.

FIGS. 14a-b are schematic cross-sections of typical embodiments with coplanar arrays of electrodes with magnetic flux lines enclosing pairs of electrodes.

FIG. 15 is a schematic depiction of a system comprising various embodimenta of the present invention used to analyze unknown materials.

### DETAILED DESCRIPTION OF THE INVENTION

After considering the following description, those skilled in the art will clearly realize that the teachings of the invention can be readily utilized in many fields of use. Some embodiments of the invention are particularly adaptable to in-vivo measurement of biological characteristics to obtain information, such as blood glucose concentration, used for patient monitoring, determination of treatment or for identification. Other embodiments are particularly suitable for measurements on samples of substances, such as liquids and powdered solids to identify, analyze, or otherwise characterize them. Thus applications range from biometrics to hazardous materials identification to industrial quality control, among others.

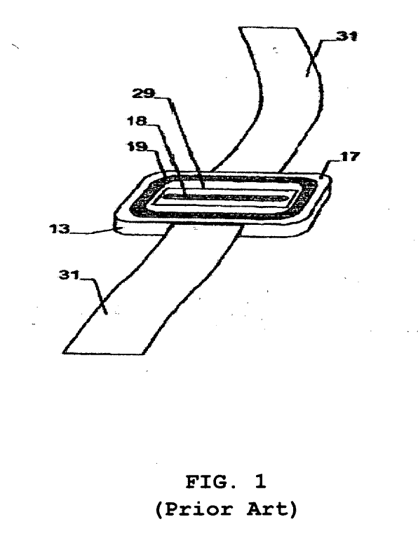

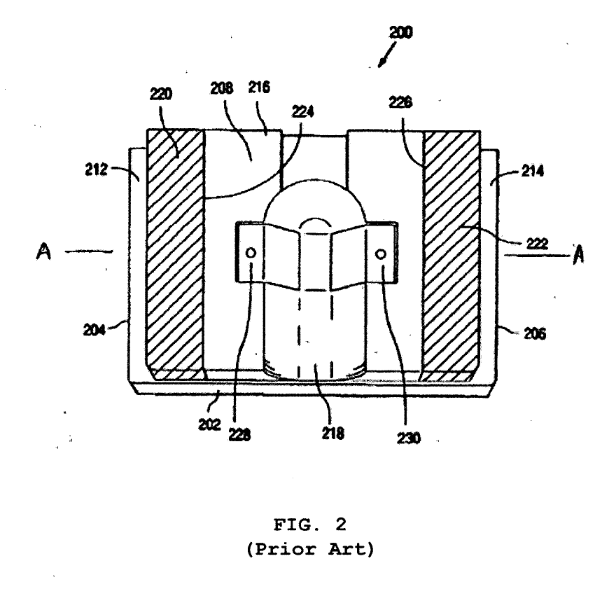

FIG. 1 shows a view of an apparatus of U.S. Pat. No. 7,315,767 by Caduff et al, in which the strip electrode 18 and the ring electrode 19 are contained in a housing 13 that is attached to a patient's arm or leg using the strap 31. It is intended that the long axis of the strip electrode be parallel to the axis of the limb.

FIG. 2 is a top view of an apparatus according to U.S. Pat. No. 6,723,048 by Fuller in which electrodes 228 and 230 are attached to support body 202 made from an electrically insulating material and extend into the gap 218 where a finger is placed. Magnets 220 and 222 are placed so their N and S poles, 224 and 225, respectively, face the gap. A power source and analyzer (not shown) are connected to the transmitter 228 and receiver 230 electrodes, respectively.

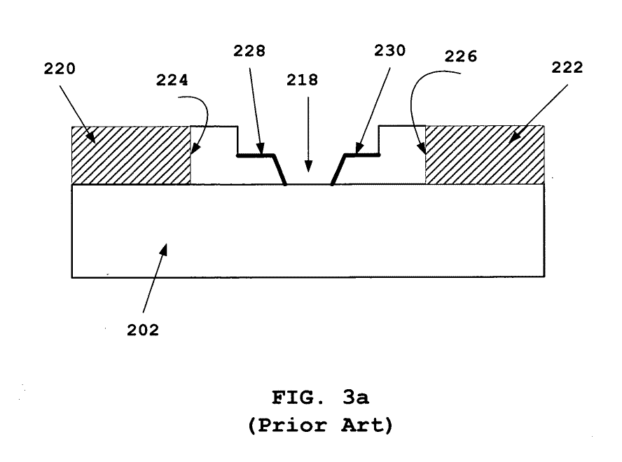

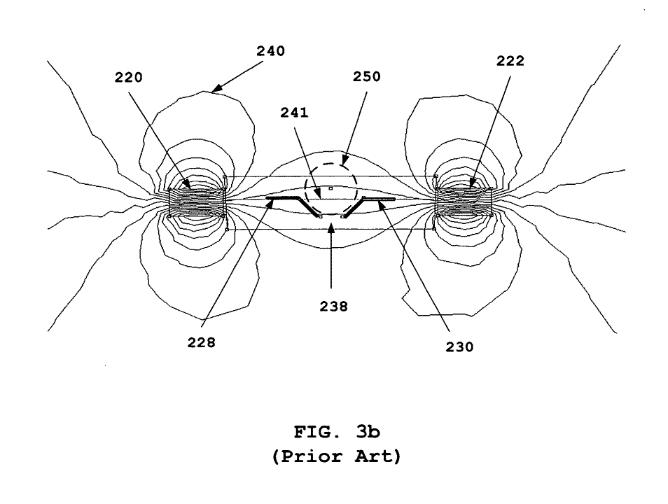

FIG. 3a depicts a vertical cross section through A-A of FIG. 2. A 2-D magnetic model representing the magnets and electrodes of FIG. 3a has been created and the results are illustrated in FIG. 3b. For consistency of comparison, magnets of the same strength (magnetic energy product of 40 megagauss-oersted (MGOe)) have been used for all the magnetic models depicted herein. The model used is a 2-D version of FEMM, version 3.3, (finite element magnetic modeling) freeware, published by David Meeker, downloaded from http://femm.foster-miller.net/wiki/HomePage on Aug. 29, 2003. This model produces magnetic ‘flux lines’ 240 that emanate from an N magnetic pole and enter an S magnetic pole. The strongest magnetic field in the sampling region is along the straight flux line 241. As can be seen from the illustration, the flux lines in this configuration of device pass generally through both of the electrodes 228 and 230 and the region where the finger is placed, represented by the dashed circle 250. The strongest electric field in the sample region occurs in the region 238 where the electrodes are closest together. Variation in location and orientation of a finger, especially elevation above the electrodes, will affect the volume of the finger that interacts with the strongest electric and magnetic fields. This variation (from different readings at different times) means that comparisons of readings to one another and to a ‘baseline’ will depend not only on the changes in the characteristic being measured (e.g., blood glucose), but also on the variability of finger placement.

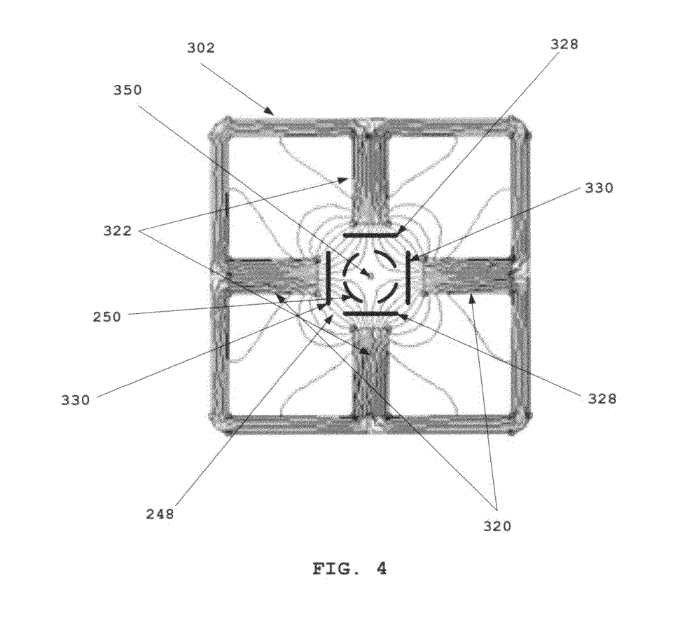

The result of the modeling of one embodiment of the present invention using a quadrupole arrangement of magnets and electrodes is illustrated in FIG. 4. This figure represents the result of a 2-D magnetic model of a cross-section through an apparatus showing only the electrodes and magnetic circuits. For simplicity of illustration, necessary electrical connections, feedthroughs, electrode supports and external electronics are not shown. Magnets with inward facing N poles 320 are adjacent to magnets with inward facing S poles 322. The magnets are supported by their attraction to a frame/box 302 made from a soft magnetic material such as low carbon steel. Each magnet is part of two magnetic circuits, as the flux emanating from a N pole 320 is split between the S poles 322 of the adjacent magnets, it travels through those magnets, the frame, and re-enters the S pole of the originating magnet in contact with the frame. This box is assembled so as to have one end with an opening that will allow insertion of a sample into the sample cavity (generally represented by the dashed circle 250) centered on an axis 350 that is also an axis of symmetry for the electrodes and magnet poles. The electrodes and magnets are arranged substantially evenly around the periphery of the sample cavity. Electrodes 328 are connected to the RF power source so as to have a complementary function (transmitter vs receiver) to adjacent electrodes 330. As used herein, transmitter (t) and receiver (r) will be understood to be complementary functions. With proper sizing and spacing of the electrodes and pole faces there is roughly the same strength of electric field around the periphery 248 of the sample cavity and roughly the same strength of magnetic field around the periphery of the sample cavity. The RF signal from any given transmitter electrode is roughly equally divided between the adjacent receiver electrodes and the magnetic flux emanating from any one (inward facing) magnetic pole is roughly equally divided between the adjacent magnetic poles. Thus, this configuration may be considered to effectively have four magnetic fields and four electrode pairs.

The benefits that arise from this embodiment of the present invention include the following: First, the volume of a sample that is inspected by relatively high electric fields is increased and is distributed around the entire circumference of the sample. This increases the signal level and also, by inspecting more of the sample, increases the reliability by reducing the signal dependence on axial rotation of the sample. Second, if a sample moves off axis away from one electrode, or one pair, it moves closer to another electrode or pair. Thus, the reduction in signal due to moving away from one pair is compensated by the increase in signal due to moving toward the other pair. The result is a decreased dependence of signal on the exact location of the sample.

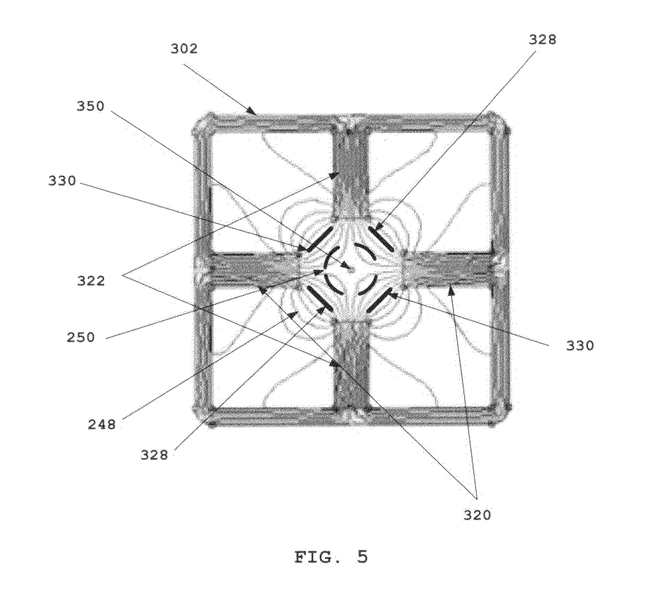

In the preceding embodiment of the present invention, the orientation of the magnetic flux lines is substantially parallel to the orientation of the electric field lines within the sample cavity. Thus, flux lines that intersect one electrode usually intersect an adjacent electrode. Because the response of molecules and the transmission of RF signals are affected by the orientation and strength relationship between the electric and magnetic fields, it may be possible to increase the strength of the signal by making the magnetic flux substantially orthogonal to the electric field, as illustrated in FIG. 5. Note that in this arrangement, any one electrode is fully within the region of only one cusp of the magnetic fields.

One embodiment of the present invention as illustrated in FIG. 5 can be obtained from the device of FIG. 4 by adding the capability to rotate the electrodes 45° about the cavity axis. The result of the modeling of this embodiment of the present invention using a quadrupole arrangement of magnets and electrodes is illustrated in FIG. 5. This figure represents the 2-D magnetic model of a cross-section through an apparatus showing only the electrodes and magnetic circuits. For simplicity of illustration, necessary electrical connections, feedthroughs, electrode supports and external electronics are not shown. The reference numbers for FIG. 5 are the same as those used for FIG. 4. For particular applications it may be advantageous to operate at an intermediate rotation, but this can be determined by simple experimentation.

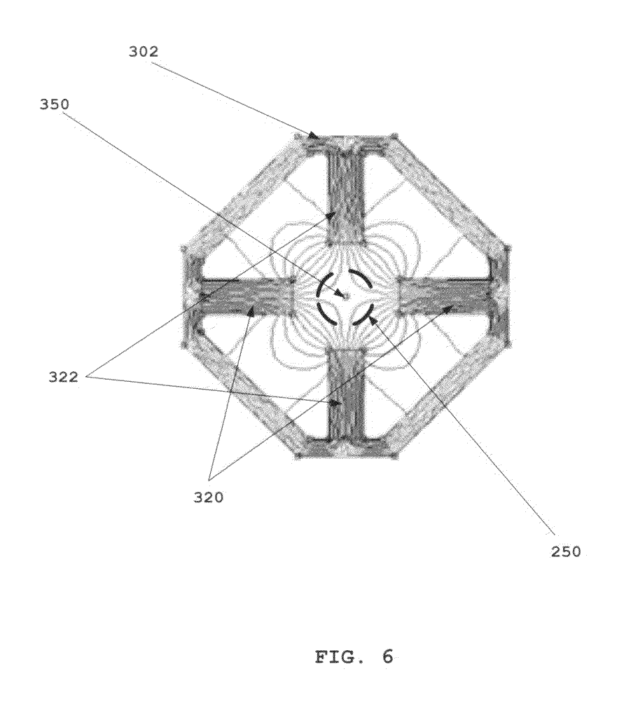

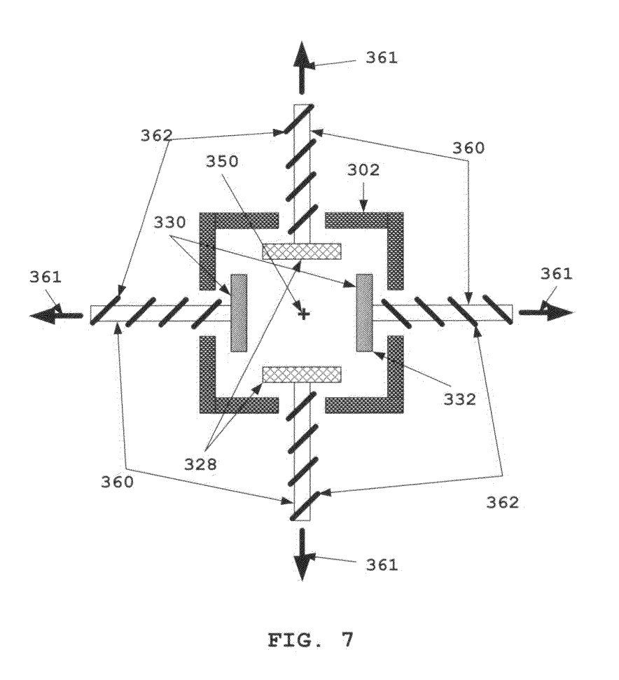

For applications requiring portability and to reduce cost, it is desirable to make the devices as small as possible, while preserving essential advantages and sample cavity size. FIG. 6 illustrates the 2-D magnetic model of a cross-section through an apparatus showing only the magnetic circuits in which the frame size and magnet length have been reduced compared to the model upon which FIG. 4 is based. The electrodes are not illustrated in this figure since they may be placed in the orientation of FIG. 4, FIG. 5, or intermediate orientations as discussed previously. These changes in size reduced the maximum extent of the device from the cavity axis 350. As can be seen, the essential shape of the magnetic flux lines within the sample cavity did not change. Further reductions in size are possible by judicious reduction in wall thickness of the box/frame 302 and optimization of the aspect ratio (height to width) of the magnets 320 and 322.

As discussed above, it is not only desirable to have consistent relative location between the electrodes and the sample, it is also desirable, for maximum signal strength, to have the sample in close proximity to the electrodes. Moveable electrodes retain the flexibility to accommodate samples of different size while achieving these desirable goals. FIG. 7 illustrates the electrodes of one such embodiment, compatible with the device of FIG. 4. The magnets are not shown in this illustration. Also, there may be devices that don't require magnets. By providing moveable supports 360 for the electrodes 328 and 330, they are moveable between distances from the axis 350 that represent most of the range of sample sizes. External actuators, not shown, serve to pull the electrodes in the direction indicated by the arrows, 361 to their maximum separation when a sample is to be inserted. When the actuator is released, springs 362 push the electrodes into contact with the inserted sample (not shown).

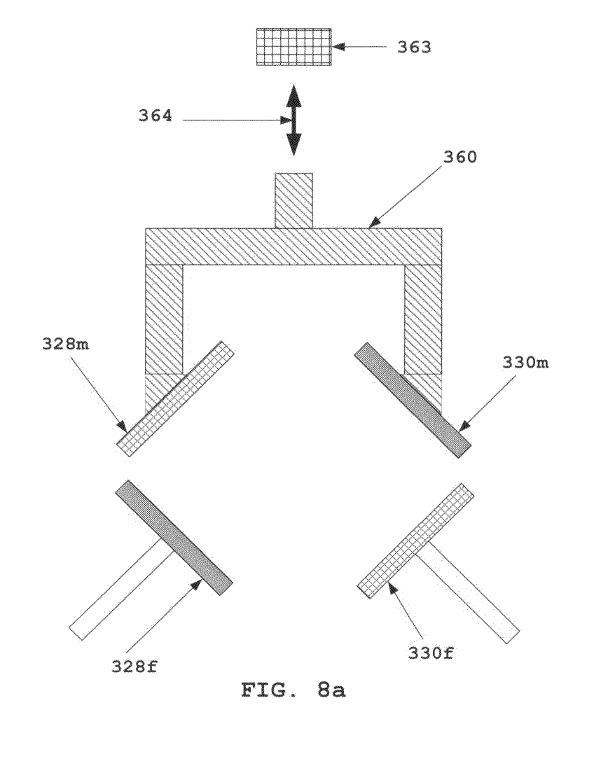

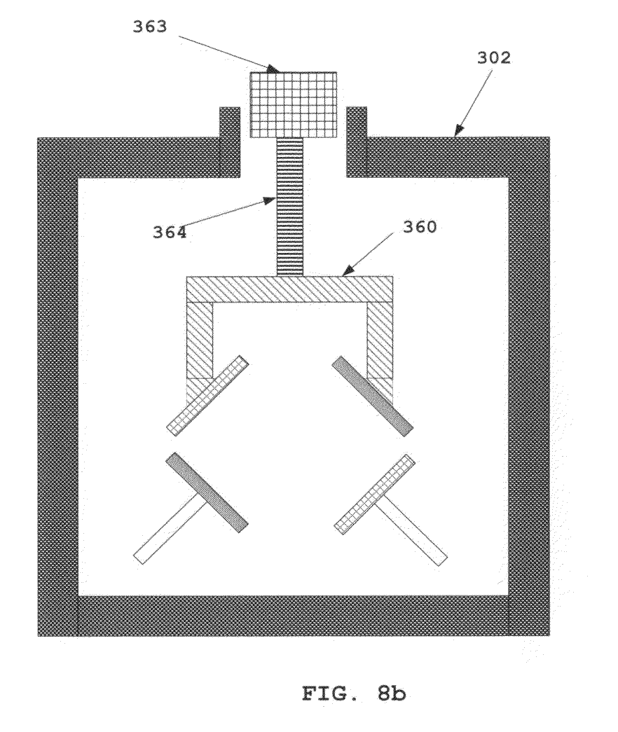

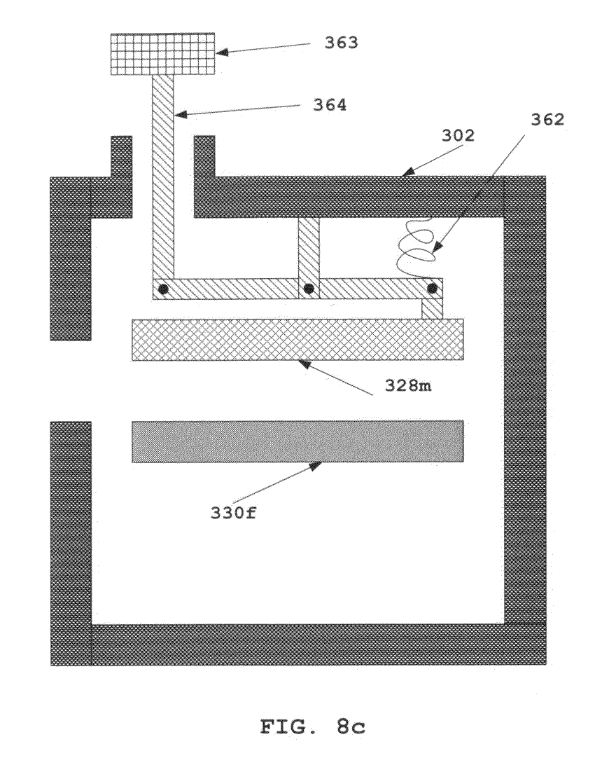

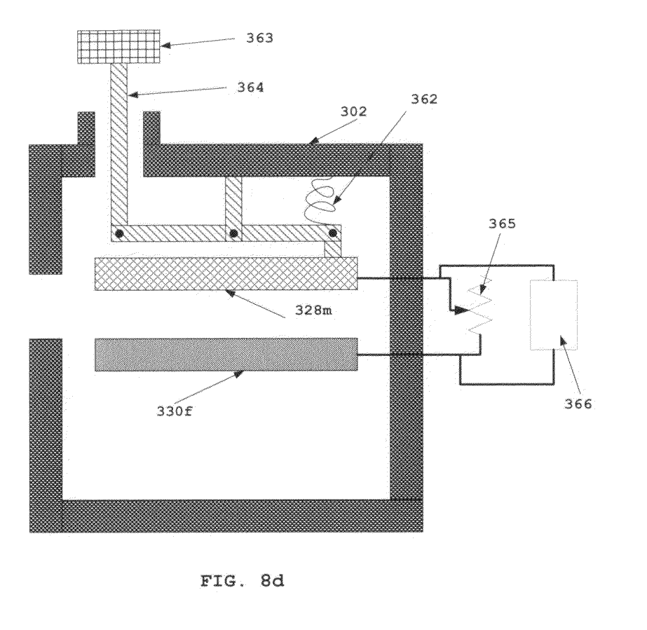

Other embodiments of the present invention, have some electrodes fixed and some moveable, a typical example of which is illustrated in FIGS. 8a-d. As illustrated in FIG. 8a, the lower electrodes 328f and 330f are fixed with respect to the magnets, box, sample, and sample cavity (not shown). The upper electrodes 328m and 330m are attached to a non-conducting support 360 that is attached to a linkage represented schematically by 364 that is actuated by pushing a button 363 embedded in the wall of the box. FIGS. 8b-d illustrate two possible configurations of the apparatus with two fixed and two moveable electrodes. The linkage can be a simple spring loaded plunger (FIG. 8b) or a lever arrangement (FIG. 8c) that causes the upper electrodes to rise when the button is pushed, increasing the space available for sample insertion. After a sample is inserted into the sample cavity in contact with the lower electrode structure, the button is released and a spring 362 causes the linkage to move the upper electrode structure into contact with the sample. It will be advantageous during data analysis for a measure of the sample size to be known. As shown in FIG. 8d, a transducer 365 and associated electronics 366 can be used to indicate relative position of the electrodes. For clarity, the sample is not illustrated in FIGS. 8a-d.

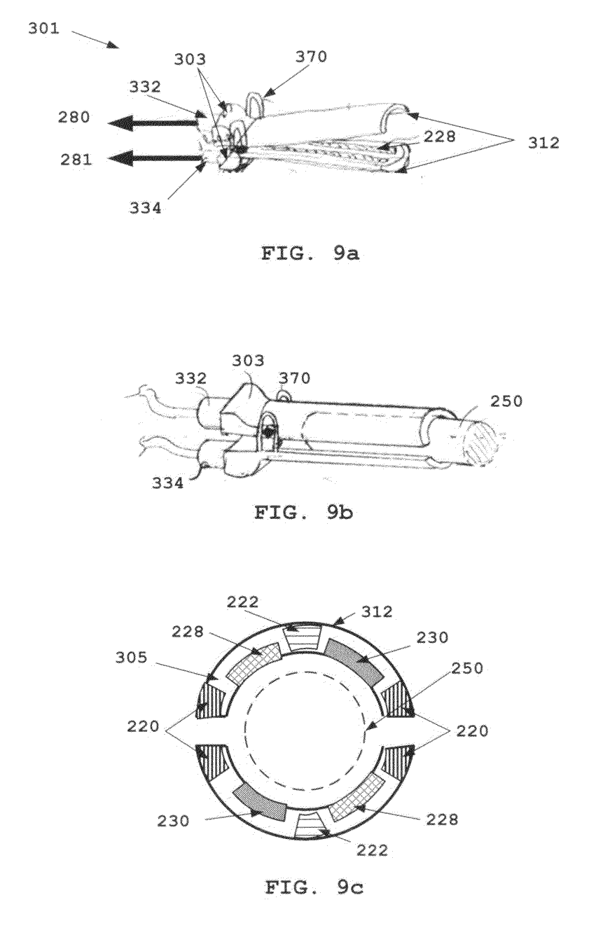

Miniaturization of the sensor assembly allows it to be packaged into a device that clips onto a sample (such as a human finger). A typical embodiment is illustrated in FIGS. 9a-9c. This apparatus is similar in appearance to that used in medical offices and operating rooms for the measurement of blood oxygen. FIG. 9a is an overall view of the sensor assembly 301. Outer shells 312 are connected together at an expandable hinge 370. The hinge is spring loaded in such a way that it normally holds the shells together. When the actuators 303 are pressed together, the shells 312 open, allowing a sample 250 (see FIG. 9b) to be inserted between them. As the actuators are released, the shells move apart at the hinge 370 allowing uniform contact with the sample along its inserted length, as illustrated in FIG. 9b. Electrical signals are transmitted via the electrical connectors 332 and 334 from external signal transmitter 280 and receiver 281 (not shown). A cross section through the shell of FIG. 9b is illustrated in FIG. 9c. Magnets 220 and 222 are in contact with the shells 312 made from a magnetically soft material. Insulating material fills the space 305 between the shell 312 and electrodes 228 and 230 and serves to isolate and support the electrodes. It can be appreciated that such a device could be combined in the same housing with other measurement means, such as for blood oxygen, pulse rate, or body temperature. Such a combination would be particularly advantageous to monitor multiple aspects of blood chemistry and patient condition during an operation or other medical treatment.

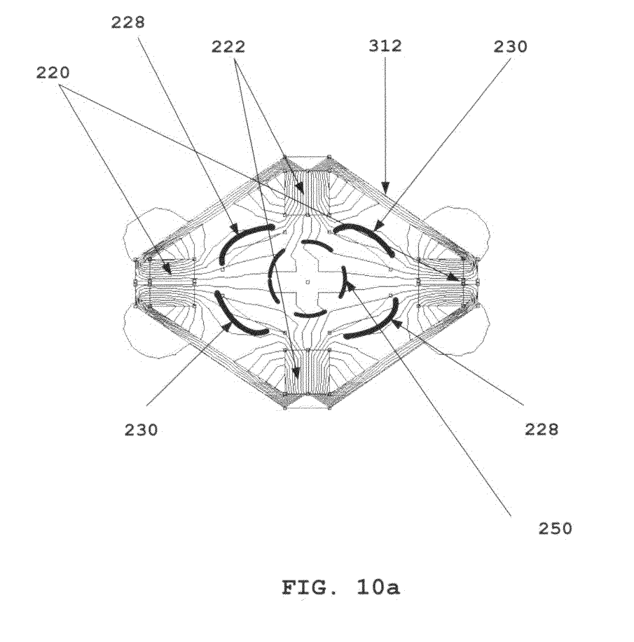

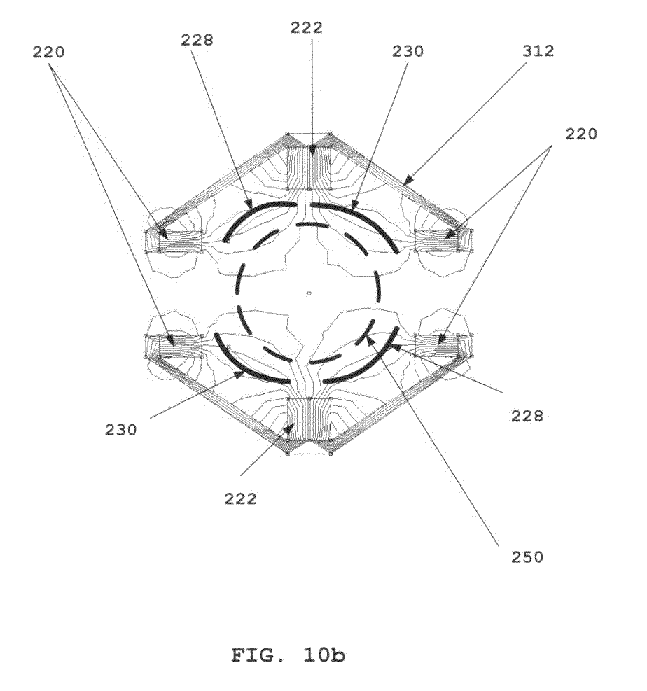

FIGS. 10a and 10b are graphical results from a 2-D magnetic model of a cross-section through an apparatus showing only the electrodes and magnetic circuit based on the apparatus from FIGS. 9a-c. The FIG. 10a results represent the model wherein the shells 312 are together, and incorporate a sample 250. The FIG. 10b results represent the model wherein the shells 312 are separated and incorporate a sample 250 of larger diameter. Thus, for a large range of sample size, significant portions of the sample are in close proximity to electrode pairs in regions of maximum electric and magnetic fields within the sampling volume.

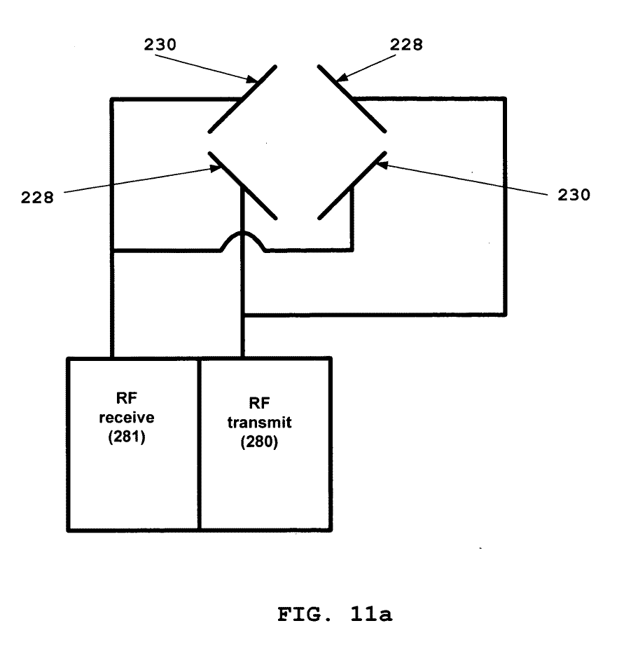

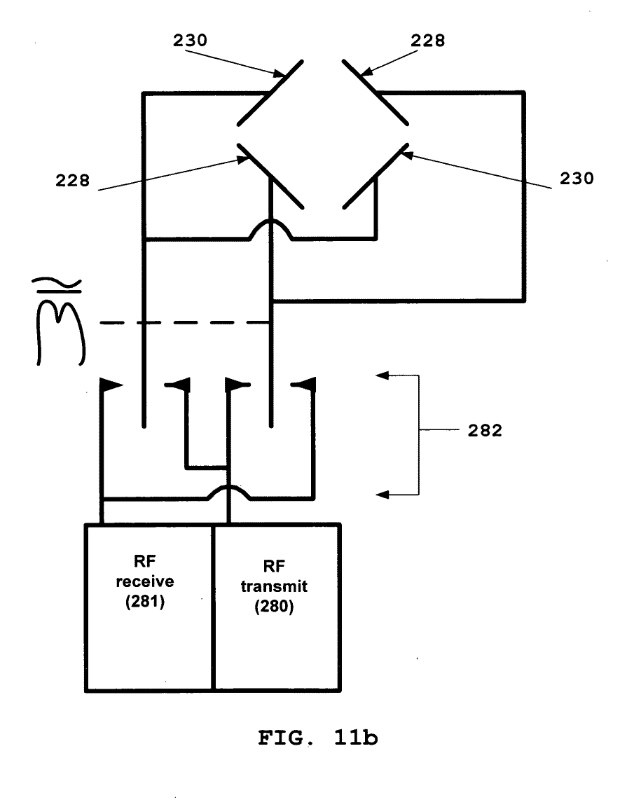

To improve the reliability of the readings and data analysis, multiple readings are often taken and averaged. In the case of some embodiments of the present invention, further improvement is also obtained if the t-r functions of the electrodes are switched between readings. This helps to compensate for slight instrumental bias in the signals transmitted/received at different electrodes. FIGS. 11a-11b illustrate a circuit for some embodiments in which the functions of the electrodes are (FIG. 11b) and are not (FIG. 11a) electronically switchable. In FIG. 11a, a transmitter 280 of RF signal is connected by an electrically parallel arrangement to t electrodes 228. R electrodes 230 are connected by an electrically parallel arrangement to an RF signal receiver 281. In FIG. 11b, electronically activated switches are added, represented by 282 for a double pole double throw (dpdt) relay, to enable simultaneous switching of the functionality of the t-r sets of electrodes. In use, a spectrum taken with one switch position would be averaged with a spectrum taken immediately thereafter in the other switch position.

The sensor may be used as part of a method used to determine various attributes of the sample. The method comprises placing a sample within the sample cavity of the sensor. An electromagnetic field of varying frequencies is applied to the transmitting electrodes as described previously. An RF signal receiver is connected to the receiving electrodes as described previously and is used to measure and store one or more electromagnetic signal characteristics. In the case where the sensor is used in combination with other sensors (i.e., oxygen sensor, temperature, etc.), those observations are also completed. The electromagnetic signal characteristics are processed, combined, and stored. It may be advantageous to combine, average and store the analyses of multiple tests of the sample to improve the accuracy of the analysis. As previously mentioned, it may be advantageous to alternate the function of the t and r electrodes of the sensor during the analysis. The results of the processed, combined, and stored analyses can be communicated, along with other sample or environmental data, to an apparatus that contains computer-readable media containing databases of reference sample data and reference measured and stored electromagnetic signal characteristics. The computer-readable media also typically contain analysis algorithms used to compare the measured and stored electromagnetic signal characteristics of the sample under test to those found within the database. The analysis algorithms are used to compare the measured and stored electromagnetic signal characteristics of the sample under test to those found within the database. The results of the analysis algorithms will determine at least one characteristic of the sample.

The sensor may be used as part of a system used to determine attributes of the sample. Typically, the transmitting electrodes of the sensor will be connected to an electromagnetic generator as previously described. Similarly, the receiving electrodes will be connected to an RF signal receiver as previously described. An apparatus for switching the function of the t and r electrodes may also be part of the system as previously described. The generator and receiver may be connected to an apparatus used for storing and analyzing the data. The apparatus may be local to the instrument or may be centrally located. The apparatus typically contains a processor for combining measured and stored electromagnetic signal characteristics from one or more analysis sessions. The apparatus also typically contains computer-readable media which contain databases of reference sample data and reference measured and stored electromagnetic signal characteristics. The computer-readable media also typically contain analysis algorithms used to compare the measured and stored electromagnetic signal characteristics of the sample under test to those found within the database. Finally, the apparatus will contain a communication device if the measured and stored electromagnetic signal characteristics are to be communicated to a database held at a remote location.

Although the aforementioned embodiments provide increased signal strength and consistency when measurements are taken using a substantially cylindrical sample, it may be desirable in some applications to use an arrangement that is designed to be used in contact or proximity with other sample geometries. Examples of other sample geometries comprise planar, wrapped in a spiral configuration, completely enclosed (such as in a cube), spherical, etc. Configuring multiple electrodes and electric fields following the teachings of the present invention in a planar, or nearly planar, array will provide the increased signal strength discussed above. Moreover, arranging the sensor components so that the electrodes are concentric, or at least equidistant, eliminates, or reduces, the need to orient the sensor array parallel to the axis of a sample.

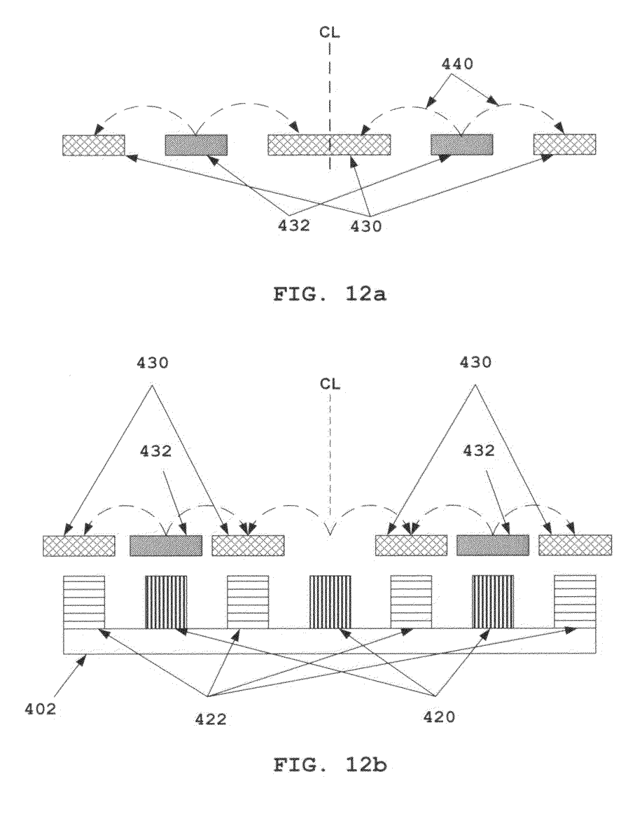

FIGS. 12a-c are illustrations of cross sections through disc or annular shaped coplanar r 430 and t 432 electrodes and arranged in magnetic fields such that a magnetic flux line 440 emanating from one pole and entering an opposite pole generally exits one electrode and enters a complementary electrode and is generally parallel to the electric fields between the two electrodes (in the sample). The magnets are not shown in FIG. 12a. FIG. 12b illustrates magnets 420 (N pole facing the electrodes) and 422 (S pole facing the electrodes) arrayed behind the electrodes on a keeper plate 402 to generate the flux lines. It is to be understood that the functions of each electrode and the polarities of the magnets could be switched (that is, t for r and N for S, etc.).

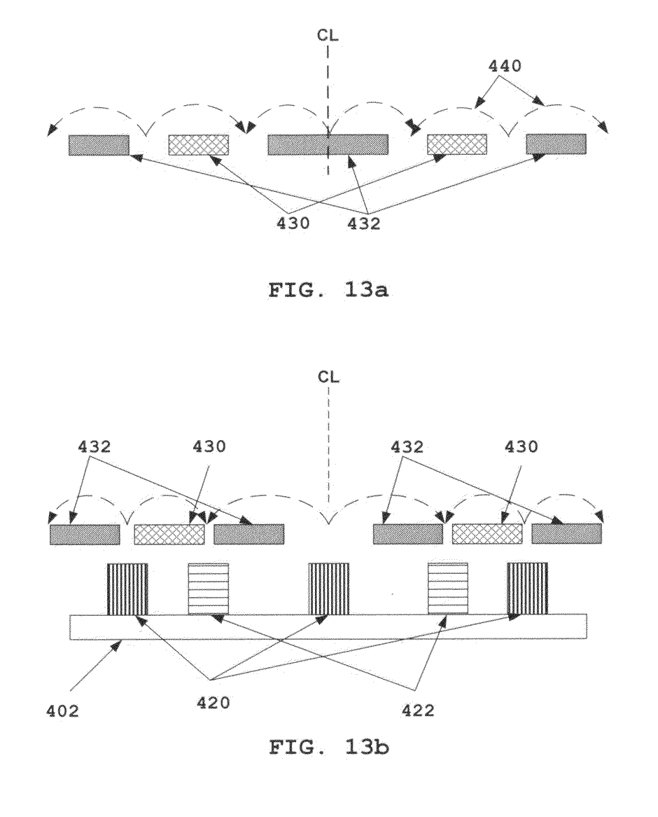

FIGS. 13a-b are illustrations of cross sections through disc or annular shaped coplanar r and t electrodes 430 and 432 arranged in magnetic fields such that a flux line 440 emanating from one pole and entering the opposite pole generally encloses a single electrode and is substantially orthogonal to the electric field lines emanating from that electrode. The magnets are not shown in FIG. 13a. FIG. 13b illustrates magnets 420 (N pole facing the electrodes) and 422 (S pole facing the electrodes) arrayed behind the electrodes on a keeper plate 402 to generate the flux lines. It is to be understood that the functions of each electrode and the polarities of the magnets could be switched (that is, t for r and N for S, etc.).

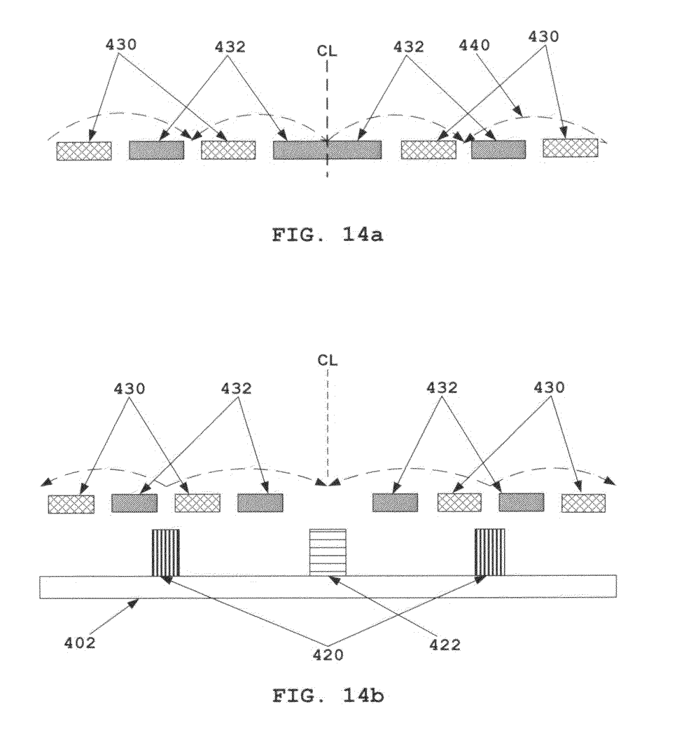

FIGS. 14a-b are illustrations of cross sections through disc or annular shaped coplanar r and t electrodes 430 and 432 arranged in magnetic fields such that a flux line 440 emanating from one pole and entering the opposite pole generally encloses a t-r pair of electrodes. The magnets are not shown in FIG. 14a. FIG. 14b illustrates magnets 420 (N pole facing the electrodes) and 422 (S pole facing the electrodes) arrayed behind the electrodes on a keeper plate 402 to generate the flux lines. It is to be understood that the functions of each electrode and the polarities of the magnets could be switched (that is, t for r and N for S, etc.).

Simple experimentation will determine which of the above configurations is optimal for a given application. Figures of merit during the experimentation include parameters such as signal strength, repeatability, stability, and accuracy, among others. To improve physical conformance of the above described electrodes to a sample, the electrodes could be made to be somewhat flexible and mounted in a pliant insulating material such as silicone rubber, rubber, plastic, and fabric, among others.

For the applications where the sample is not in-vivo, such as the identification and analysis of solid (powdered, granular or machineable) and liquid materials, the sample cavity can be sized to precisely support a sample holder, such as a test tube, cuvette, etc., and the sample cavity can be oriented with its axis vertical. In a process where a flowing fluid is to be analyzed, the sample cavity can be open at both ends to enclose a pipe. In these cases, electrodes and magnets can be mounted in fixed positions, as, for example, the embodiments shown in FIGS. 4 and 5.

In applications of generalized in-the-field identification or analysis of materials using portable analytical equipment, a sample spectrum [or “feature vector”] is obtained which may then be compared to spectra in a database to search for a match. Such a device, if made portable, would be extremely useful in law enforcement, customs enforcement, hazardous materials response, and transportation security, among others. However, several challenges can arise when performing in-the-field analysis under actual enforcement, emergency or surveillance conditions. Some of these are: First, as the amount of material loaded into the sample holder is varied, the signal strength changes. For instance, less material may be available than is required to fill the sample holder to the ‘standard’ level. To compensate for this, the database would need to contain stored spectra for different amounts of any given material. This increases the size of the required database. Second, as the database size increases, due to the tens, or hundreds, of thousands of possible materials and the redundancy due to material amount, three things may happen: a) search times may become very long; b) the chance may increase that multiple materials will ‘match’, resulting in ambiguous identification; and c) the database size may become too large to be stored in the memory local to a portable device.

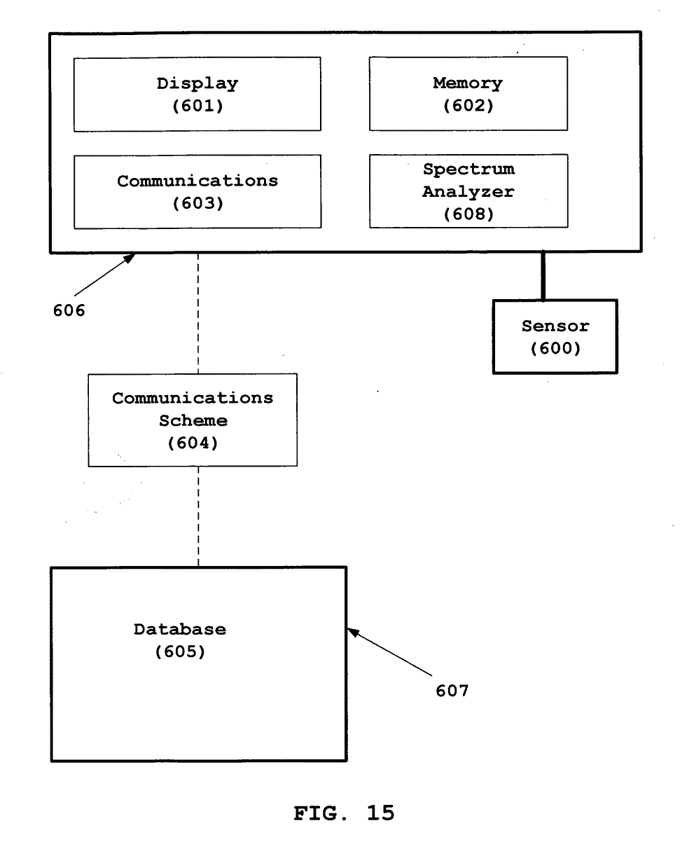

Other embodiments of an improved apparatus and method for using embodiments of the present invention for ex-vivo materials analysis and identification may be described as follows and a typical example is illustrated in FIG. 15. A sensor 600 may be connected to a local device 606. The device's spectrum analyzer 608 (or the local computer that manipulates the spectrum to produce a reduced set of data points) may communicate with a communication device 603 such as a laptop computer connectible to the internet or a PDA/cell phone connectible to a wireless network, or other communication devices and schemes 604 used to communicate to a central database 605. On-board the local device could be enough memory 602 to store the reference data for a limited number of materials. Reference data can consist of attributes such as: the actual scan data, or its reduced equivalent; the state of the material (solid, liquid, etc.); appearance information (e.g., color, opacity, etc.); the amount of fill of the sample holder, e.g., <⅓, ⅓-⅔, >⅔. The complete dataset of reference materials may be maintained at a central server computer 607 that can communicate with remote portable devices (by internet, wireless, or other communication scheme 604). When a user of the local device wishes to perform an analysis on a substance, a portion of the sample is placed into the sample holder (marked with fill indicator lines) and the sample holder is inserted into the sample cavity. A background scan of the empty sample holder may be performed first. Then, observations about the sample, such as state, color and sample holder fill amount may be entered into the device. An exemplary method to accomplish this may be to display a series of questions and answers as text on a menu on the communication device display screen 601. The user may then place a curser over the correct answer to select it. Alternately, some such attributes could be sensed by means incorporated into the sensor.

A scan, or scans, of the substance may be completed and the data suitably manipulated. The resulting data are first compared with reference data stored locally. If no match is found, the data, along with the observed sample information, may be sent digitally (and properly encoded for security) to the central server using one or more of the communication schemes discussed previously 604. There, the data are compared to data in the database 605. Because the database can be partitioned by the substance attributes and amount (e.g., clear, colorless liquid, >⅔ full) the search can proceed more quickly than if the entire database were searched. Moreover, there may be a reduced likelihood of false matches. Once a match is found (e.g., percentage of ethanol in water) the information may be communicated back to the local portable station, where it is displayed for the local user. Optionally, the reference data can be added to the database in the local system.

Although various embodiments that incorporate the teachings of the present invention have been shown and described in detail herein, those skilled in the art can readily devise many other varied embodiments that still incorporate these teachings.

What is claimed is:

1. An apparatus for detecting the change in an RF signal comprising:
a. a sample cavity;
b. at least two pairs of magnets 320, 322 positioned adjacent to the sample cavity;
c. wherein the at least two pairs of magnets are arranged with one magnetic pole of each magnet oriented inwardly in the direction toward the sample cavity, with adjacent magnets having inward facing poles of opposite magnetic polarity; and
d. at least two pairs of electrodes 328, 330 each pair of electrodes comprising a transmitting electrode and a receiving electrode, positioned adjacent to the sample cavity and arranged with adjacent electrodes having complementary functions.

2. The apparatus of claim 1 wherein the sample cavity has a periphery and wherein the at least two pairs of magnets 320, 322 are substantially evenly distributed around the periphery of the sample cavity and the at least two pairs of electrodes 328, 330 are substantially evenly distributed around the periphery of the sample cavity.

3. The apparatus of claim 2 wherein the sample cavity has substantially cylindrical geometry.

4. The apparatus of claim 1 wherein at least one of the at least two pairs of electrodes 328, 330 is flexibly arranged with respect to the sample cavity.

5. The apparatus of claim 4 further comprising an apparatus 365, 366 to determine the spatial relationship of the electrodes.

6. The apparatus of claim 1 wherein at least one of the at least two pairs of electrodes 328, 330 and at least one of the at least two pairs of magnets 320, 322 are flexibly arranged with respect to the sample cavity.

7. The apparatus of claim 6 further comprising an apparatus 365, 366 to determine the spatial relationship of the electrodes, the spatial relationship of the magnets, or the spatial relationship of both the electrodes and the magnets.

8. The apparatus of claim 1 further comprising devices to measure other attributes of a sample positioned within the sample cavity.

9. The apparatus of claim 1 wherein the at least two pairs of electrodes 328, 330 are arranged such that magnetic lines of flux substantially pass from one electrode of each pair to the other electrode of each pair.

10. The apparatus of claim 1 wherein the at least two pairs of electrodes 328, 330 are arranged such that magnetic lines of flux substantially enclose each electrode of each pair.

11. The apparatus of claim 1 wherein the relative position of the at least two pairs of electrodes 328, 330 can be varied with respect to the position of the at least two pairs of magnets 320, 322.

12. A system for detecting the change in an RF signal comprising:
a. a sensor 600 comprising;
a. a sample cavity having a periphery;
b. at least two pairs of magnets 320, 322 positioned adjacent to the sample cavity;
c. wherein the at least two pairs of magnets 320, 322 are substantially evenly distributed around the periphery of the sample cavity;
d. wherein the at least two pairs of magnets 320, 322 are arranged with one magnetic pole of each magnet oriented inwardly in the direction toward the sample cavity and arranged with adjacent magnets having inward facing poles of opposite magnetic polarity;
e. at least two pairs of electrodes 328, 330, each pair comprising a transmitting electrode and a receiving electrode, positioned adjacent to the sample cavity and arranged with adjacent electrodes having complimentary functions;
f. wherein the at least two pairs of electrodes 328, 330 are substantially evenly distributed around the periphery of the sample cavity;
b. an apparatus 280 for generating an electromagnetic signal of varying frequencies connected to the transmitting electrodes; and
c. an apparatus 281 for measuring and storing a characteristic of an electromagnetic signal and connected to the receiving electrodes.

13. The system of claim 12 further comprising an apparatus 282 for switching the transmitting and receiving functions within the electrode pairs during an analysis session.

14. The system of claim 12 further comprising an apparatus 606 to measure and store attributes of the sample.

15. The system of claim 14 further comprising:
a. a database 605 comprising reference sample data, and reference measured and stored electromagnetic signal characteristics;
b. a processor for combining measured and stored electromagnetic signal characteristics from at least one analysis session with sample attribute data;
c. a communication device 603, 604 to transmit the combined measured and stored electromagnetic signal characteristics and associated sample attribute data to a database; and
d. a computer-readable medium containing one or more analysis algorithms for comparing the combined measured and stored electromagnetic signal characteristics with reference data within the database to determine at least one characteristic of the sample.

16. A method for determining at least one characteristic of a sample comprising:
a. placing a sample within the sample cavity of a sensor 600;
b. generating an electromagnetic field of varying frequencies and applying the electromagnetic field to transmitting electrodes within the sensor;
c. measuring and storing a characteristic of an electromagnetic signal obtained from receiving electrodes within the sensor;
d. performing additional analysis procedures to measure and store other attributes of a sample positioned within the sample cavity;
e. processing and combining measured and stored electromagnetic and attribute data from at least one analysis session;
f. communicating the processed and combined measured and stored electromagnetic and attribute data to a database; and
g. performing analysis procedures for comparing the combined measured and stored electromagnetic and attribute data with other data within the database to determine at least one characteristic of the sample.

17. The method of claim 16 wherein the sensor comprises:
a. a sample cavity having a periphery;
b. at least two pairs of magnets 320, 322 positioned adjacent to the sample cavity;
c. wherein the at least two pairs of magnets 320, 322 are substantially evenly distributed around the periphery of the sample cavity;
d. wherein the at least two pairs of magnets 320, 322 are arranged with one magnetic pole of each magnet oriented inwardly in the direction toward to sample cavity and arranged with adjacent magnets having poles of opposite magnetic polarity;
e. at least two pairs of electrodes 328, 330, each pair comprising a transmitting electrode and a receiving electrode, positioned adjacent to the sample cavity and arranged with adjacent electrodes having complementary functions; and
f. wherein the at least two pairs of electrodes 328, 330 are substantially evenly distributed around the periphery of the sample cavity.
